(19) United States
(12) Patent Application Publication
(10) Pub. No.: US 2026/0190847 A1
(43) Pub. Date: Jul. 2, 2026

(54) PANEL FORMING APPARATUS AND PANEL FORMING METHOD USING THE SAME

(71) Applicant: SAMSUNG DISPLAY CO., LTD., YONGIN-SI (KR)

(72) Inventors: HONGCHUL SHIN, Yongin-si (KR); TETSUYA OKAMOTO, Yongin-si (KR); MINSEOK KANG, Yongin-si (KR); GEUNYOUNG YU, Yongin-si (KR)

(21) Appl. No.: 19/409,940

(22) Filed: Dec. 5, 2025

(30) Foreign Application Priority Data
Jan. 2, 2025 (KR) 10-2025-0000260

(51) Int. Cl. H10K 71/50; H10K 59/12; H10P 72/00; H10P 72/50

(52) U.S. Cl. CPC H10K 71/50; H10K 59/1201; H10P 72/0441; H10P 72/57

(57) ABSTRACT

A panel forming apparatus including a first mold, and a second mold disposed on the first mold. The first mold includes an alignment part, a first jig disposed on the alignment part, and a shaft disposed under the alignment part, the shaft moves the alignment part and the first jig upward and downward, and the second mold includes a first support including a plurality of first holes defined therein, a second jig disposed under the first support, and including an opening defined therein, a third jig disposed in the opening, a plurality of first cylinders disposed on the first support and extending through the plurality of first holes, respectively, and connected to the third jig, and a second cylinder disposed on the first support.

### CROSS-REFERENCE TO RELATED APPLICATIONS

This application claims priority under 35 U.S.C. § 119 to Korean Patent Application No. 10-2025-0000260, filed on January 2, 2025 in the Korean Intellectual Property Office, the disclosure of which is incorporated by reference in its entirety herein.

### 1. TECHNICAL FIELD

Embodiments of the present disclosure described herein relate to a panel forming apparatus and a panel forming method using the same.

### 2. DISCUSSION OF RELATED ART

Various electronic devices include a display device for displaying images to users, such as a smart phone, a digital camera, a laptop computer, a navigation system, and a smart television. The display device generates an image and provides the users with the image through a display screen.

With the recent development of technology of display devices, various types of display devices have been developed. For example, a display device having a curved side surface is being developed. A display device having a curved side surface includes a display panel that displays an image. However, research is being conducted concerning a technology for easily molding the side surface of the display panel into a curved surface.

### SUMMARY

Embodiments of the present disclosure provide a panel forming apparatus that may easily form a side surface of a display panel into a curved surface, and a panel forming method using the same.

According to an embodiment of the present disclosure, a panel forming apparatus may include a first mold, and a second mold disposed on the first mold, the first mold may include an alignment part, a first jig disposed on the alignment part, and a shaft disposed under the alignment part, the shaft moves the alignment part and the first jig upward and downward, and the second mold may include a first support, including a plurality of first holes defined therein, a second jig disposed under the first support, the second jig including an opening defined therein, a third jig disposed in the opening, a plurality of first cylinders disposed on the first support to pass, the plurality of first cylinders extending through the plurality of first holes, respectively, and connected to the third jig, and a second cylinder disposed on the first support.

In an embodiment, the first mold may include a plurality of pins disposed on the first jig, the plurality of pins is arranged to be spaced apart from each other in a first direction and a second direction crossing the first direction, the plurality of first pins may extend in a third direction perpendicular to the first direction and the second direction, the first jig moves upward and downward along the third direction, and the plurality of pins may overlap a plurality of guide grooves defined at a periphery of the second jig, the plurality of guide grooves extending in the third direction.

In an embodiment, the plurality of pins may be disposed in the plurality of guide grooves and moves in the third direction along the plurality of guide grooves when the first jig is moved in the third direction.

In an embodiment, a lower surface of the second jig may be disposed to be higher than a lower surface of the third jig.

In an embodiment, the first jig may directly contact the second jig after first directly contacting the third jig first, and the third jig is moved in the third direction along the opening when the first jig is moved upward due to the first jig directly contacting the third jig.

In an embodiment, the first jig may directly contact the third jig after directly contacting the second jig first when the first jig is moved upward.

In an embodiment, the first jig, the second jig, and the third jig may include a heating wire.

In an embodiment, the second mold may further include a second support disposed on the first support, the second support includes a second hole defined therein, and the second cylinder extends through the second hole.

In an embodiment, the second mold may further include a third support disposed on the second support, and a plurality of coupling parts coupling the second support and the third support to each other.

In an embodiment, the first mold may further include a first rail disposed on a side surface of the alignment part, and the second mold may further include a second rail connected to the first support and the second support.

In an embodiment, a plurality of fourth holes may be defined on an upper surface of the first jig.

In an embodiment, the second mold may further include a bar disposed on lower surfaces of the plurality of first cylinders and an upper surface of the third jig.

In an embodiment, the second mold may further include a measurement part disposed on the first support, and positioned at centers of the plurality of first cylinders in a first direction, and a bracket disposed on an upper surface of the measurement part, and disposed on a lower surface of the second cylinder.

In an embodiment, the panel forming apparatus may further include a third rail connected to the first mold and the second mold.

According to an embodiment of the present disclosure, a panel forming method may include preparing a first mold that may include an alignment part, a first jig disposed on the alignment part, and a shaft disposed under the alignment part, the shaft moves the alignment part and the first jig upward and downward, preparing a second mold that may include a first support, a plurality of first holes defined therein, a second jig disposed under the first support, the second jig including an opening defined therein, a third jig disposed in the opening, a plurality of first cylinders disposed on the first support, the plurality of first cylinders extending through the plurality of first holes, respectively, and connected to the third jig, and a second cylinder disposed on the first support, providing a preliminary display panel onto the first jig, applying a thrust to the plurality of first cylinders and the second cylinder, moving the first support downward, moving the first jig upward, bringing an upper surface of the preliminary display panel and the second jig or the third jig into direct contact with each other, and stopping the first mold.

In an embodiment, the first mold may include a plurality of pins disposed on the first jig, the plurality of pins is arranged to be spaced apart from each other in a first direction and a second direction crossing the first direction, a plurality of guide grooves extending in a third direction perpendicular to the first direction and the second direction may be defined at a periphery of the second jig, and the panel forming method may further include moving the alignment part in the first direction and the second direction so that the plurality of pins overlap the plurality of guide grooves in the third direction, and moving the plurality of pins in the third direction and coupling the plurality of pins to the plurality of guide grooves.

In an embodiment, the bringing of the upper surface of the preliminary display panel and the second jig or the third jig into direct contact with each other may include bringing the upper surface of the preliminary display panel and the third jig into direct contact with each other, and after bringing the upper surface of the preliminary display panel and the third jig into direct contact with each other, bringing the upper surface of the preliminary display panel and the second jig and the third jig into direct contact with each other.

In an embodiment, the bringing of the upper surface of the preliminary display panel and the second jig or the third jig into direct contact with each other may include bringing the upper surface of the preliminary display panel and the second jig into direct contact with each other, and after bringing the upper surface of the preliminary display panel and the second jig into direct contact with each other, bringing the upper surface of the preliminary display panel and both the second jig and the third jig into direct contact with each other.

In an embodiment, the applying of the thrust to the first cylinders and the second cylinder may include applying a first thrust to the plurality of first cylinders, respectively, and applying a second thrust to the second cylinder, wherein the first thrust and the second thrust are different from each other.

According to an embodiment of the present disclosure, an electronic device may include a camera module, a display device that displays an image corresponding to a captured image acquired through the camera module, and a case accommodating the display device and the camera module, the display device may include a display panel formed by a first mold and a second mold facing each other upward and downward and being moved to become closer to each other upward and downward, and including an edge part having a round shape, the first mold may include an alignment part, a first jig disposed on the alignment part, and a shaft disposed under the alignment part, the shaft moves the alignment part and the first jig upward and downward, and the second mold may include a first support including a plurality of first holes defined therein, a second jig disposed under the first support, the second jig including an opening defined therein, a third jig disposed in the opening, a plurality of first cylinders disposed on the first support, the plurality of first cylinders extending through the plurality of first holes, respectively, and connected to the third jig, and a second cylinder disposed on the first support.

### BRIEF DESCRIPTION OF THE DRAWINGS

The above and other objects and features of the present disclosure will become apparent by describing in detail non-limiting embodiments thereof with reference to the accompanying drawings.

FIG. 1 is a side view of a panel forming apparatus according to an embodiment of the present disclosure.

FIG. 2 is a perspective view of a frame, to which a panel forming apparatus is coupled, according to an embodiment of the present disclosure.

FIG. 3 is a side view of a state, in which the panel forming apparatus of FIG. 1 and the frame of FIG. 2 are coupled to each other according to an embodiment of the present disclosure;

FIG. 4 is a perspective view of a first mold according to an embodiment of the present disclosure.

FIG. 5 is a perspective view of an alignment part illustrated in FIG. 4 according to an embodiment of the present disclosure.

FIG. 6 is a plan view of an alignment part illustrated in FIG. 4 according to an embodiment of the present disclosure.

FIG. 7 is a plan view illustrating first and second drivers and first to fourth rail parts after a connection plate is separated from the first to fourth rail parts in FIG. 6 according to an embodiment of the present disclosure.

FIG. 8 is a perspective view of the first and second drivers and the first to fourth rail parts illustrated in FIG. 7 according to an embodiment of the present disclosure.

FIG. 9 is a perspective view of a front side of the second rail part illustrated in FIG. 8 after the second part is separated separately according to an embodiment of the present disclosure.

FIGS. 10A and 10B are perspective views of a second mold according to embodiments of the present disclosure.

FIG. 11 is a perspective view of an electronic device including a display panel manufactured by using a panel forming apparatus according to an embodiment of the present disclosure.

FIG. 12 is an exploded perspective view of an electronic device according to an embodiment.

FIG. 13 is a block diagram of the electronic device illustrated in FIG. 12 according to an embodiment of the present disclosure.

FIG. 14 is a cross-sectional view of a display module and a window of a display device illustrated in FIG. 12 according to an embodiment of the present disclosure.

FIG. 15 is a view illustrating a cross section of the display panel illustrated in FIG. 14, according to an embodiment of the present disclosure.

FIG. 16 is a view illustrating a cross section of the display panel illustrated in FIG. 15, according to an embodiment of the present disclosure.

FIG. 17 is a side view of a panel forming apparatus according to an embodiment of the present disclosure.

FIGS. 18A to 18C are views illustrating processes of a display panel forming apparatus according to embodiments of the present disclosure.

FIGS. 18A to 18F are enlarged views of portion AA’ of FIG. 18C according to embodiments of the present disclosure.

### DETAILED DESCRIPTION OF EMBODIMENTS

In the specification, the expression that a first component (or area, layer, part, etc.) is “on”, “connected with”, or “coupled with” a second component means that the first component is directly on, connected with, or coupled with the second component or means that a third component is interposed therebetween. An expression that a first component (or area, layer, part, etc.) is “directly on”, “directly connected with”, or “directly coupled with” a second component means that no intervening elements are present.

The same reference numerals refer to the same components. Also, in drawings, the thickness, ratio, and dimension of components may be exaggerated for effectiveness of description of technical contents. The term “and/or” includes one or more combinations in each of which associated elements are defined.

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “below”, “on”, “above”, etc. are used to describe the correlation of components illustrated in drawings. The terms are relative concepts, and are described with respect to directions indicated in the drawings.

It will be understood that the terms “include”, “comprise”, “have”, and the like specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

The present disclosure concerns a panel forming apparatus that includes first and second molds. A preliminary display panel may be provided on a first jig on the first mold. The first jig may be moved upward and connected to a second jig on the second mold that is moved downward. The first jig may be connected to the second jig through a plurality of pins on the first jig being received into guide grooves along a periphery of the second jig. Therefore, when the first jig is moved upward, a misalignment between the first jig of the first mold and second and third jigs of the second mold may be prevented.

The second mold includes a plurality of first cylinders and a second cylinder. The plurality of first cylinders may apply a first thrust to the third jig. The second cylinder may apply a second thrust to the second jig. The first and second thrusts may be different from each other to increase the reliability of the process of forming the display panel.

In the panel forming apparatus, the process of forming the panel may include a flat part of the display panel first directly contacting the third jig and the edge part of the display panel then directly contacting the second jig. Therefore, a phenomenon in which the edge part of the display panel is bent due to the thrust received by the second jig and the display panel is misaligned, may be prevented.

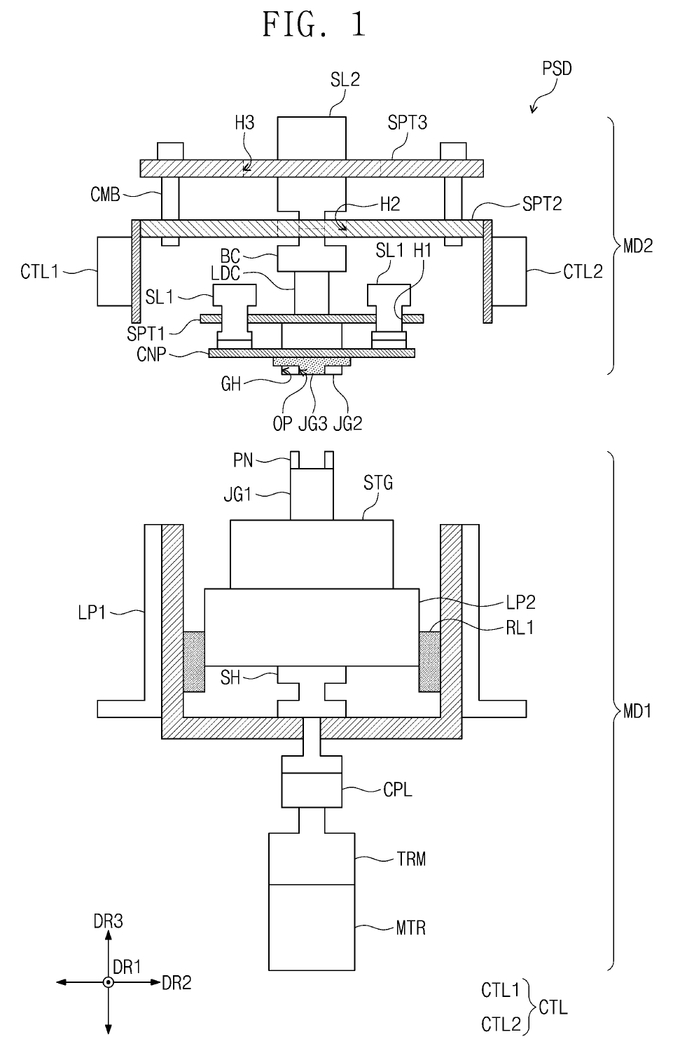

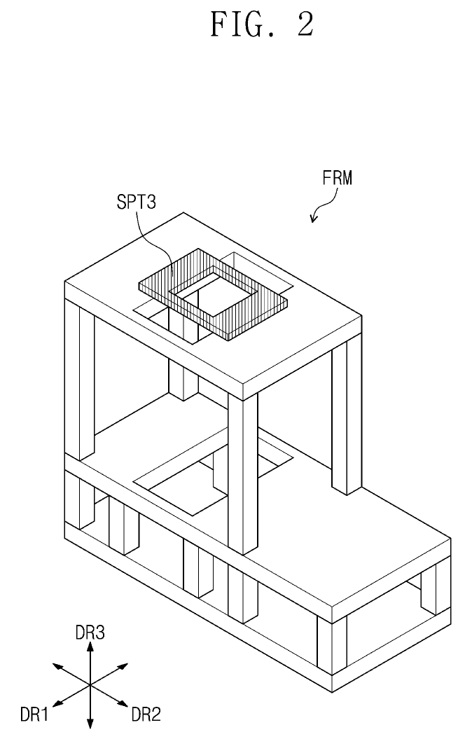

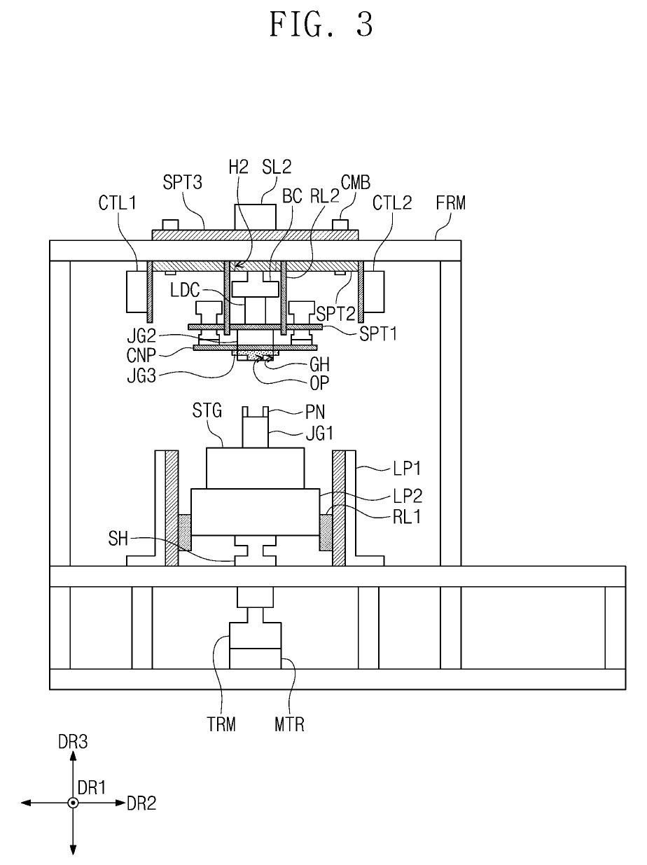

FIG. 1 is a side view of a panel forming apparatus according to an embodiment of the present disclosure. FIG. 2 is a perspective view of a frame, to which a panel forming apparatus is coupled, according to an embodiment of the present disclosure. FIG. 3 is a side view of a state, in which the panel forming apparatus of FIG. 1 and the frame of FIG. 2 are coupled to each other;

Referring to FIGS. 1 to 3, in an embodiment a panel forming apparatus PSD may include a first mold MD1, a second mold MD2, and a frame FRM.

A first support part LP1 of the first mold MD1 may contact (e.g., directly contact) the frame FRM. A lower surface of a third support SPT3 and an upper surface of a second support SPT2 of the second mold MD2 may contact (e.g., directly contact) the frame FRM. Accordingly, the first mold MD1 and the second mold MD2 may be disposed in the frame FRM.

In an embodiment, the first mold MD1 may include a motor MTR, a transmission TRM, a coupling CPL, a shaft SH, a first support part LP1, a second support part LP2, an alignment part STG, a first jig JG1, pins PN, and a first rail RL1.

In an embodiment, the motor MTR may provide a force that moves the first mold MD1 in an upward direction, such as the third direction DR3. The motor MTR may move the second support part LP2, the alignment part STG, and the first jig JG1 in the third direction DR3.

The transmission TRM may adjust a reduction ratio of the motor MTR. In an embodiment, a force that moves the second support part LP2, the alignment part STG, and the first jig JG1 may be increased even when their movement speeds are decreased when the second support part LP2, the alignment part STG, and the first jig JG1 are moved in the third direction DR3, by adjusting the reduction ratio of the motor MTR with the transmission TRM. The transmission TRM may increase a force that is provided by the first jig JG1 in the third direction DR3.

The coupling CPL may transmit the force provided by the motor MTR, to the shaft SH. In an embodiment, a rotational force provided by the motor MTR may be changed to a force in the third direction DR3 through the coupling CPL.

The shaft SH may be disposed under the alignment part STG (e.g., in a direction opposite to the third direction DR3) to move the alignment part STG and the first jig JG1 upward and downward (e.g., in the third direction DR3 and a direction opposite to the third direction DR3). In an embodiment, the shaft SH may be disposed under the second support part LP2 to move the second support part LP2, the alignment part, and the first jig JG1 in the third direction DR3. The shaft SH may receive the force provided by the motor MTR and transmit the force in an upward direction, such as the third direction DR3, which is provided by the motor MTR, to the second support part LP2, the alignment part STG, and the first jig JG1. The shaft SH may move the alignment part STG and the first jig JG1 in both an upward direction (e.g., in the third direction DR3) and a downward direction (e.g., in a direction opposite to the third direction DR3).

In an embodiment, the second support part LP2 may be connected to (e.g., directly connected thereto in the third direction DR3) the shaft SH to receive a force that the shaft SH transmits in the third direction DR3. The second support part LP2 may be moved in the third direction DR3.

In an embodiment, the alignment part STG may be connected to (e.g., directly connected thereto in the third direction DR3) the second support part LP2 to be moved in the third direction DR3. The first jig JG1 may be connected to (e.g., directly connected thereto in the third direction DR3) the alignment part STG to be moved in the third direction DR3. A detailed description of the alignment part STG and the first jig JG1 will be described later.

The first rail RL1 may contact (e.g., directly contact) a side surface of the second support part LP2. In an embodiment, the first rail RL1 may prevent the second support part LP2, the alignment part STG, and the first jig JG1 from being moved in a horizontal direction, such as the first direction DR1 and/or a second direction DR2 when the second support part LP2, the alignment part STG, and the first jig JG1 are moved in the third direction DR3. Furthermore, in an embodiment, when the second support part LP2, the alignment part STG, and the first jig JG1 are moved in the third direction DR3, the first rail RL1 may move in the third direction DR3 to help the second support part LP2, the alignment part STG, and the first jig JG1 to move in the third direction DR3. Other configurations of the first mold MD1 will be described later.

In an embodiment, the second mold MD2 may include a first support SPT1, a second support SPT2, a third support SPT3, a plurality of first cylinders SL1, a second cylinder SL2, a second jig JG2, a third jig JG3, a bracket BC, a measurement part LDC, a controller CTL, a coupling part CMB, and a bar CNP.

The measurement part LDC may be disposed on first support SPT1 (e.g., disposed directly thereon in the third direction DR3). In an embodiment, the measurement part LDC may be disposed at (e.g., positioned at) a center of the first cylinders SL1 in the second direction DR2. The measurement part LDC may be disposed under the bracket BC (e.g., directly thereunder in a direction opposite to the third direction DR3). The measurement part LDC may be disposed between the first support SPT1 and the second support SPT2 (e.g., in the third direction DR3). The measurement part LDC may measure a thrust. For example, in an embodiment the measurement part LDC may be a force sensor (e.g., a load cell). The measurement part LDC may measure a thrust that is applied to the first support SPT1 by the second cylinder SL2.

The bracket BC may be disposed on the measurement part LDC. For example, in an embodiment, the bracket BC may be disposed directly on an upper surface of the measurement part LDC (e.g., in the third direction DR3). In an embodiment, the bracket BC may be disposed on a lower surface of the second cylinder SL2, and may directly contact the second cylinder SL2. The bracket BC may pass through (e.g., extend therethrough) a second hole H2 of the second support SPT2. The bracket BC may be disposed between the first support SPT1 and the second support SPT2 (e.g., in the third direction DR3). In an embodiment, when the second cylinder SL2 applies a thrust to the bracket BC in a direction that is opposite to the third direction DR3, the bracket BC may directly contact the second cylinder SL2 to transmit the thrust to the first support SPT1. The bracket BC may surface-contact the measurement part LDC. The bracket BC may transmit a uniform thrust to the measurement part LDC during a thrust transmission process, and the thrust may be uniformly transmitted to the first support SPT1.

In an embodiment, the controller CTL may be disposed on a side surface of the second support SPT2 (e.g., lateral side surfaces in the second direction DR2). The controller CTL may control the first cylinders SL1 and the second cylinder SL2 to provide a constant thrust, respectively. In an embodiment, the controller CTL may include a first controller CTL1 and a second controller CTL2. In an embodiment, the first controller CTL1 and the second controller CTL2 may be disposed to face each other with respect to the second direction DR2. The first controller CTL1 may control thrusts of the first cylinders SL1, and the second controller CTL2 may control a thrust of the second cylinder SL2. Alternatively, the first controller CTL1 may control the thrust of the second cylinder SL2, and the second controller CTL2 may control the thrusts of the first cylinders SL1.

The bar CNP may be disposed on (e.g., disposed directly thereon) lower surfaces of the first cylinders SL1 and an upper surface of the third jig JG3. The bar CNP may be connected to the first cylinders SL1 and the third jig JG3. The first cylinders SL1 and the third jig JG3 are connected through the bar CNP so that the thrusts provided by the first cylinders SL1 may be directly transmitted to the third jig JG3 through the bar CNP.

In an embodiment, the thrusts provided by the first cylinders SL1 may be transmitted to the third jig JG3, and the thrust provided by the second cylinder SL2 may be transmitted to the second jig JG2 through the first support SPT1. Accordingly, the thrusts of the second jig JG2 and the third jig JG3 may be adjusted through the first cylinders SL1, the second cylinder SL2, and the bar CNP, respectively.

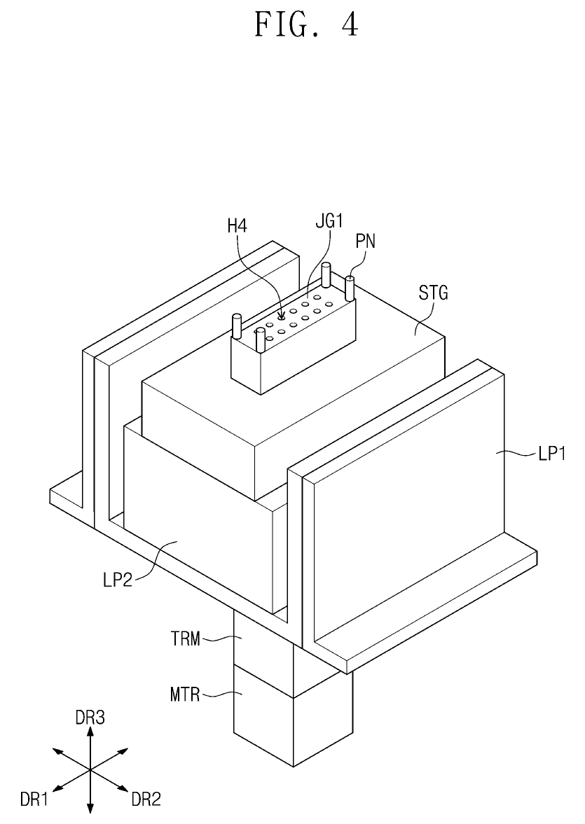

FIG. 4 is a perspective view of a first mold according to an embodiment of the present disclosure.

Referring to FIGS. 1 and 4, in an embodiment the first mold MD1 may include a motor MTR, a transmission TRM, a coupling CPL, a shaft SH, a first support part LP1, a second support part LP2, an alignment part STG, a first jig JG1, pins PN, and a first rail RL1.

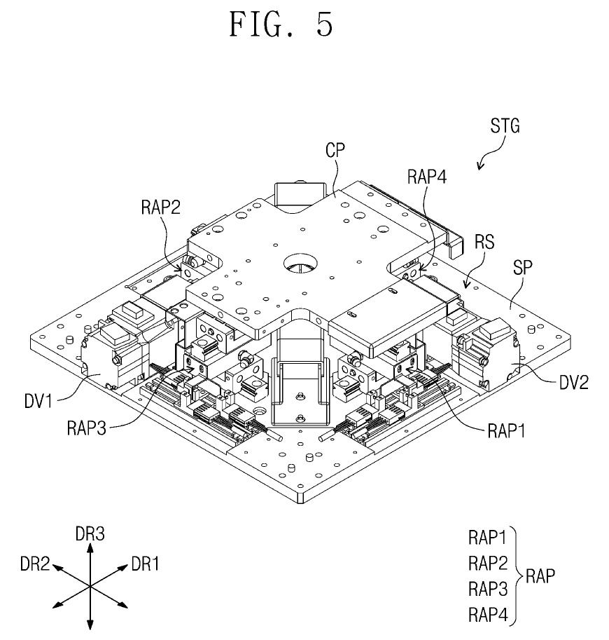

The alignment part STG may be disposed on the second support part LP2 (e.g., disposed directly thereon in the third direction DR3). In an embodiment, an upper surface of the alignment part STG may be moved in the first direction DR1 or the second direction DR2 on a plane that is defined by the first and second directions DR1 and DR2. While the first and second directions DR1, DR2 are shown in FIG. 4 as being horizontal directions perpendicular to each other and to the third direction DR3, the first and second directions DR1, DR2 may be horizontal directions crossing each other at various different angles. Although the alignment part STG is simplified and illustrated in FIG. 4, the alignment part STG will be described in detail in FIGS. 5 to 9.

The first jig JG1 may be disposed on the alignment part STG (e.g., disposed directly thereon in the third direction DR3). For example, a lower surface of the first jig JG1 may directly contact an upper surface of the alignment part STG. In an embodiment, the first jig JG1 may be disposed on the alignment part STG (e.g., disposed directly thereon in the third direction DR3), and a display panel DP (see FIG. 11) may be disposed on an upper surface of the first jig JG1.

A plurality of fourth holes H4 may be defined in the upper surface of the first jig JG1. In an embodiment, the fourth holes H4 may be arranged to be densely disposed at a center of the upper surface of the first jig JG1 (e.g., in a plan view). In an embodiment, when the display panel DP is disposed on the first jig JG1, the display panel DP may be vacuum-bonded to the upper surface of the first jig JG1 through the fourth holes H4 disposed in a central portion of the first jig JG1.

In an embodiment, the first jig JG1 may include a heating wire. In an embodiment in which the first jig JG1 includes the heating wire and the display panel DP is disposed on the upper surface of the first jig JG1 to be formed, the heat bonding molding of the display panel DP may be performed.

A plurality of pins PN may be disposed on the first jig JG1. For example, the plurality of pins PN may be disposed directly on an upper surface of the first jig JG1. In an embodiment, the pins PN may be arranged to be spaced apart from each other in the first direction DR1 and the second direction DR2. While the plurality of pins PN in an embodiment shown in FIG. 4 includes four pins, embodiments of the present disclosure are not necessarily limited thereto and the number of the plurality of pins PN may vary. In an embodiment, the pins PN may be disposed adjacent to (e.g., directly thereon) an apex and a periphery of the upper surface of the first jig JG1. The pins PN may extend in the third direction DR3 that is perpendicular to a plane defined by the first direction DR1 and the second direction DR2. The third direction DR3 may correspond to an upward/downward movement direction of the first jig JG1.

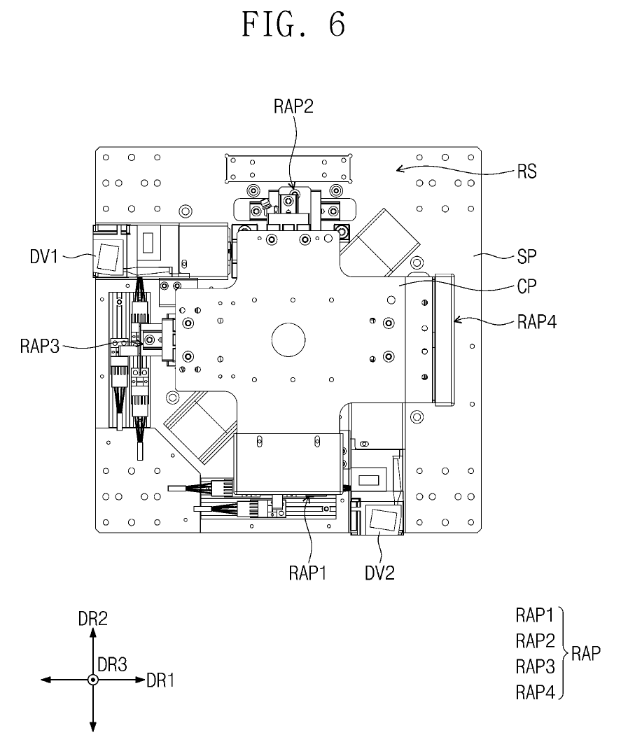

FIG. 5 is a perspective view of an alignment part illustrated in FIG. 4. FIG. 6 is a plan view of an alignment part illustrated in FIG. 4.

By way of example, in FIG. 5, a support plate SP, first and second drivers DV1 and DV2, rail parts RAP, and a connection plate CP are illustrated in a coupled state. Hereinafter, a surface of the support plate SP illustrated in FIG. 5 is referred to as a rear surface RS.

Referring to FIGS. 5 and 6, the rail parts RAP may be disposed on (e.g., disposed directly thereon) the rear surface RS of the support plate SP. In an embodiment, when viewed on a plane, the rail parts RAP may be adjacent to opposite sides of the support plate SP, which are opposite to each other in the first direction DR1, and opposite sides of the support plate SP, which are opposite to each other in the second direction DR2, respectively.

The rail parts RAPs may be coupled to the rear surface RS of the support plate SP to be moved in the first direction DR1 and the second direction DR2. The structures of the rail parts RAP will be described in detail below.

In an embodiment, the rail parts RAP may include a first rail part RAP1, a second rail part RAP2, a third rail part RAP3, and a fourth rail part RAP4. The first rail part RAP1 and the second rail part RAP2 may be spaced apart from each other in the second direction DR2. The third rail part RAP3 and the fourth rail part RAP4 may be spaced apart from each other in the first direction DR1.

The first rail part RAP1 and the second rail part RAP2 may be adjacent to opposite sides of the support plate SP, which are opposite to each other in the second direction DR2, respectively. The third rail part RAP3 and the fourth rail part RAP4 may be adjacent to opposite sides of the support plate SP, which are opposite to each other in the first direction DR1, respectively.

In an embodiment, the connection plate CP may have a cross shape (e.g., in a plan view). The connection plate CP may be disposed on (e.g., disposed directly thereon) the first to fourth rail parts RAP1 to RAP4, and may be connected to the first to fourth rail parts RAP1 to RAP4. In an embodiment, the first to fourth rail parts RAP1 to RAP4 may be moved in the first direction DR1 and the second direction DR2. As the first to fourth rail parts RAP1 to RAP4 are moved in the first direction DR1 and the second direction DR2, the connection plate CP may be moved in the first direction DR1 and the second direction DR2.

In an embodiment, when viewed on a plane, portions of the second and third rail parts RAP2 and RAP3 may not overlap the connection plate CP, and may be exposed to an outside of the connection plate CP. For example, in an embodiment an end portion in the second direction DR2 of the second rail part RAP2 and an end portion in a direction opposite to the first direction DR1 of the third rail part RAP3 may be exposed to an outside of the connection plate CP in a plan view. In an embodiment, when viewed on a plane, the first and fourth rail parts RAP1 and RAP4 may be covered by the connection plate CP, and may not be exposed to the outside.

In an embodiment, a first driver DV1 and a second driver DV2 may be disposed on (e.g., disposed directly thereon) the rear surface RS of the support plate SP. The first driver DV1 and the second driver DV2 may be connected to (e.g., directly connected thereto) the rear surface RS of the support plate SP.

The first driver DV1 may be disposed to be adjacent to one of opposite sides of the support plate SP, which are opposite to each other in the first direction DR1. The second driver DV2 may be adjacent to one of opposite sides of the support plate SP, which are opposite to each other in the second direction DR2. For example, in an embodiment the first driver DV1 may be disposed on a left side of the support plate SP in the first direction DR1. The second driver DV2 may be disposed on a right side of the support plate SP in the a direction opposite to the second direction DR2.

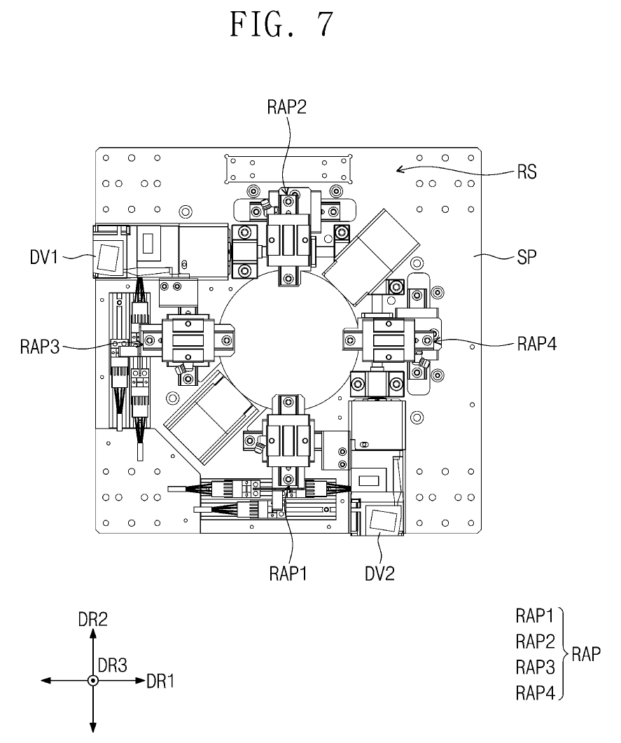

FIG. 7 is a plan view illustrating first and second drivers and first to fourth rail parts after a connection plate is separated from the first to fourth rail parts in FIG. 6.

Referring to FIG. 7, in an embodiment the first driver DV1 may extend in the first direction DR1, and may be adjacent to the third rail part RAP3 in the second direction DR2. The first driver DV1 may be adjacent to the second rail part RAP2 in the first direction DR1 and be connected to (e.g., directly connected thereto) the second rail part RAP2.

The second driver DV2 may extend in the second direction DR2, and may be adjacent to the first rail part RAP1 in the first direction DR1. The second driver DV2 may be adjacent to the fourth rail part RAP4 in the second direction DR2 and be connected to the fourth rail part RAP4.

The connection plate CP may be connected to the first and second drivers DV1 and DV2 through the second and fourth rail parts RAP2 and RAP4.

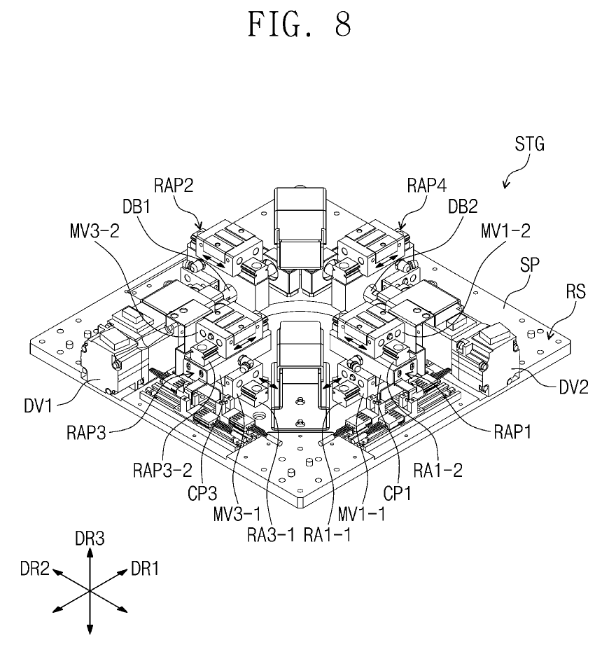

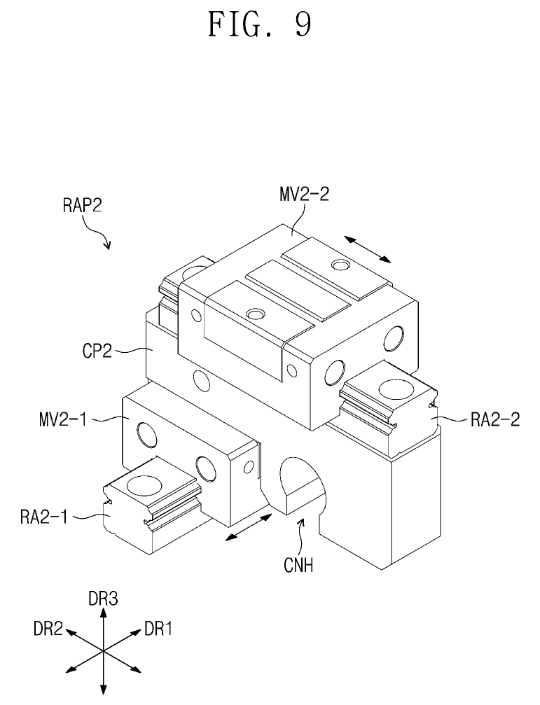

FIG. 8 is a perspective view of the first and second drivers and the first to fourth rail parts illustrated in FIG. 7. FIG. 9 is a perspective view of a front side of the second rail part illustrated in FIG. 8 after the second part is separated separately.

Referring to FIGS. 5, 8, and 9, in an embodiment the first rail part RAP1 may include a (1-1)-th rail RA1-1, a (1-1)-th movement part MV1-1, a first connection part CP1, a (1-2)-th rail RA1-2, and a (1-2)-th movement part MV1-2. Hereinafter, in the specification, movement in the first direction DR1, movement in the second direction DR2, and movement in the third direction DR3 may mean reciprocating movements.

The (1-1)-th rail RA1-1 may be disposed on (e.g., disposed directly thereon) the rear surface RS of the support plate SP and be connected to the support plate SP. The (1-1)-th rail RA1-1 may extend in the first direction DR1. The (1-1)-th movement part MV1-1 may be disposed on (e.g., disposed directly thereon) the (1-1)-th rail RA1-1, and may be coupled to the (1-1)-th rail RA1-1 to be moved along the (1-1)-th rail RA1-1. The (1-1)-th movement part MV1-1 may be moved in the first direction DR1, along the (1-1)-th rail RA1-1.

The first connection part CP1 may extend in the second direction DR2, and may be disposed on (e.g., disposed directly thereon) the (1-1)-th movement part MV1-1 to be connected to the (1-1)-th movement part MV1-1. The (1-2)-th rail RA1-2 may extend in the second direction DR2, and may be disposed on (e.g., disposed directly thereon) the first connection part CP1 to be connected to the first connection part CP1.

The (1-2)-th movement part MV1-2 may be disposed on (e.g., disposed directly thereon) the (1-2)-th rail RA1-2, and may be coupled to the (1-2)-th rail RA1-2 to be moved along the (1-2)-th rail RA1-2. The (1-2)-th movement part MV1-2 may be moved in the second direction DR2, along the (1-2)-th rail RA1-2. The connection plate CP illustrated in FIG. 5 may be disposed on (e.g., disposed directly thereon) the (1-2)-th movement part MV1-2 and be connected to the (1-2)-th movement part MV1-2.

In an embodiment, when the (1-1)-th movement part MV1-1 is moved in the first direction DR1, the first connection part CP1, the (1-2)-th rail RA1-2, and the (1-2)-th movement part MV1-2 may move in the first direction DR1 together with the (1-1)-th movement part MV1-1.

According to the configuration of the first rail part RAP1, the first rail part RAP1 may be moved in the first direction DR1 and the second direction DR2. Accordingly, the connection plate CP connected to the first rail part RAP1 may also be moved in both the first and second directions DR1 and DR2.

In an embodiment, when the (1-1)-th movement part MV1-1 is moved in the first direction DR1, the first connection part CP1, the (1-2)-th rail RA1-2, and the (1-2)-th movement part MV1-2 are moved in the first direction DR1 together with the (1-1)-th movement part MV1-1, and thus, the connection plate CP connected to the (1-2)-th movement part MV1-2 may also be moved in the first direction DR1. When the (1-2)-th movement part MV1-2 is moved in the second direction DR2, the connection plate CP connected to the (1-2)-th movement part MV1-2 may be moved in the second direction DR2.

In an embodiment, the second rail part RAP2 may have substantially the same configuration as the first rail part RAP1 although only some shapes thereof are different. In an embodiment the second rail part RAP2 may include a (2-1)-th rail RA2-1, a (2-1)-th movement part MV2-1, a second connection part CP2, a (2-2)-th rail RA2-2, and a (2-2)-th movement part MV2-2.

The (2-1)-th rail RA2-1 may be disposed on (e.g., disposed directly thereon) the rear surface RS of the support plate SP and be connected to the support plate SP. The (2-1)-th rail RA2-1 may extend in the first direction DR1. The (2-1)-th movement part MV2-1 may be disposed on (e.g., disposed directly thereon) the (2-1)-th rail RA2-1, and may be coupled to the (2-1)-th rail RA2-1 to be moved along the (2-1)-th rail RA2-1. The (2-1)-th movement part MV2-1 may be moved in the first direction DR1, along the (2-1)-th rail RA2-1

The second connection part CP2 may extend in the second direction DR2, and may be disposed on (e.g., disposed directly thereon) the (2-1)-th movement part MV2-1 and be connected to the (2-1)-th movement part MV2-1. The (2-2)-th rail RA2-2 may extend in the second direction DR2, and may be disposed on the second connection part CP2 and be connected to the second connection part CP2.

When viewed on a plane, a connection hole CNH that extends in the first direction DR1 may be defined in a portion of the second connection part CP2, which does not overlap the (2-1)-th movement part MV2-1. A first driving bar DB1 illustrated in FIG. 8 may be connected to the first driver DV1. The first driving bar DB1 may extend in the first direction DR1 and may be disposed in the connection hole CNH illustrated in FIG. 9. To clearly illustrate the connection hole CNH, the first driving bar DB1 is omitted from FIG. 9.

The (2-2)-th movement part MV2-2 may be disposed on (e.g., disposed directly thereon) the (2-2)-th rail RA2-2, and may be coupled to the (2-2)-th rail RA2-2 to be moved along the (2-2)-th rail RA2-2. The (2-2)-th movement part MV2-2 may be moved in the second direction DR2, along the (2-2)-th rail RA2-2. The connection plate CP illustrated in FIG. 6 may be disposed on (e.g., disposed directly thereon) the (2-2)-th movement part MV2-2 and be connected to the (2-2)-th movement part MV2-2.

In an embodiment, when the (2-1)-th movement part MV2-1 is moved in the first direction DR1, the second connection part CP2, the (2-2)-th rail RA2-2, and the (2-2)-th movement part MV2-2 may be moved in the first direction DR1 together with the (2-1)-th movement part MV2-1.

According to the configuration of the second rail part RAP2, the second rail part RAP2 may be moved in the first direction DR1 and the second direction DR2. Accordingly, the connection plate CP connected to the second rail part RAP2 may also be moved in the first and second directions DR1 and DR2.

In an embodiment, when the (2-1)-th movement part MV2-1 is moved in the first direction DR1, the second connection part CP2, the (2-2)-th rail RA2-2, and the (2-2)-th movement part MV2-2 are moved in the first direction DR1 together with the (2-1)-th movement part MV2-1, and thus, the connection plate CP connected to the (2-2)-th movement part MV2-2 may also be moved in the first direction DR1. When the (2-2)-th movement part MV2-2 is moved in the second direction DR2, the connection plate CP connected to the (2-2)-th movement part MV2-2 may be moved in the second direction DR2.

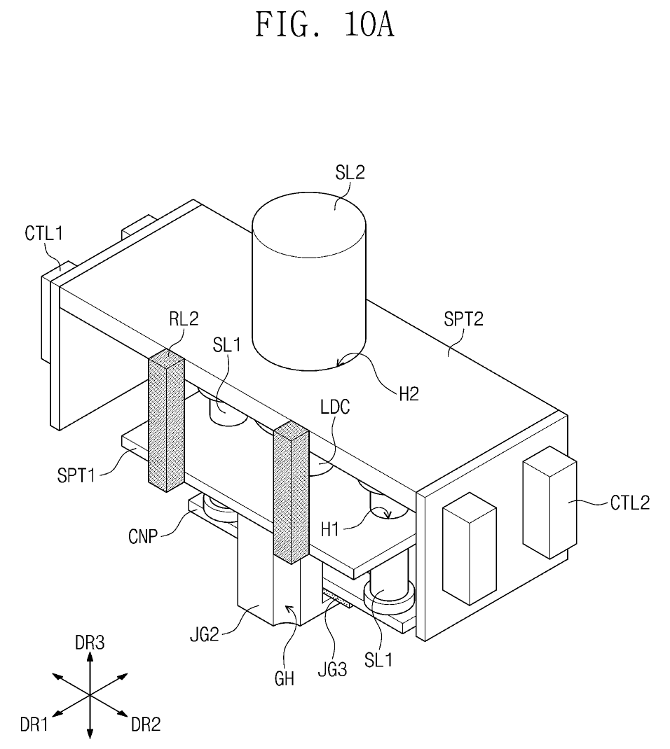

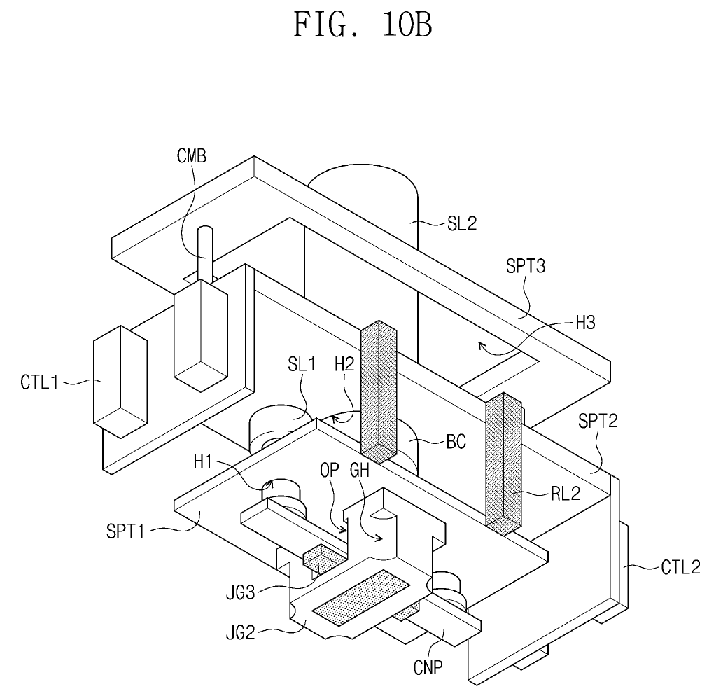

FIGS. 10A and 10B are perspective views of a second mold according to an embodiment of the present disclosure.

Referring to FIGS. 1, 10A, and 10B, in an embodiment the second mold MD2 may include a first support SPT1, a second support SPT2, a third support SPT3, a coupling part CMB, a second rail RL2, a plurality of first cylinders SL1, a second cylinder SL2, a second jig JG2, a third jig JG3, a bracket BC, a measurement part LDC, a controller CTL, and a bar CNP.

A plurality of first holes H1 may be defined in the first support SPT1. The second support SPT2 may be disposed on (e.g., in the third direction DR3) the first support SPT1. A second hole H2 may be defined in the second support SPT2, such as a central portion of the second support SPT2 (e.g., in a plan view). The third support SPT3 may be disposed on the second support SPT2 (e.g., in the third direction DR3). In an embodiment, the third support SPT3 may be disposed on (e.g., disposed directly on) the frame FRM (see FIG. 2) to fix the second mold MD2.

In an embodiment, the coupling part CMB may be connected to the second support SPT2 and the third support SPT3 to couple the second support SPT2 and the third support SPT3 to each other. In an embodiment, the second mold MD2 may include a plurality of coupling parts CMB. The second support SPT2 and the third support SPT3 may be coupled by the coupling part CMB to stably dispose the second mold MD2 in the frame FRM.

The second rail RL2 may be connected to (e.g., directly connected thereto) the first support SPT1 and the second support SPT2. When the second cylinder SL2 applies thrust, the first support SPT1 may be moved in a direction (e.g., a downward direction) that is opposite to the third direction DR3. In this case, the second rail RL2 may extend downward to move the first support SPT1 downward.

In an embodiment, a plurality of first cylinders SL1 may be connected to the third jig JG3. The first cylinders SL1 may be connected to the third jig JG3 through the bar CNP. The first cylinders SL1 may pass through (e.g., extend through) the first holes H1, and may be disposed on (e.g., disposed directly thereon) the first support SPT1. In an embodiment, the first cylinders SL1 may apply a specific thrust to the third jig JG3 according to an input value of the first controller CTL1 or the second controller CTL2.

The cylinder SL2 may be disposed on the first support SPT1 (e.g., disposed directly thereon in the third direction DR3). The second cylinder SL2 may pass through (e.g., extend through) the second hole H2, and may be disposed on the second support SPT2. The second cylinder SL2 may apply a thrust to the first support SPT1, and the thrust provided by the second cylinder SL2 may be applied to the second jig JG2 disposed under the first support SPT1. In an embodiment, the second cylinder SL2 may apply a specific thrust to the second jig JG2 according to an input value of the first controller CTL1 or the second controller CTL2.

In an embodiment, the second jig JG2 may be disposed under the first support SPT1 (e.g., in a direction opposite to the third direction DR3). An opening OP may be defined in the second jig JG2. In an embodiment, the second jig JG2 may include a heating wire. Since the second jig JG2 includes the heating wire, the display panel DP may be heat-bonded during the bonding process of the display panel DP (see FIG. 11).

In an embodiment, a plurality of guide grooves GH may be defined in a periphery of the second jig JG2. The guide grooves GH may extend in the third direction DR3. The guide grooves GH may overlap the pins PN (see FIG. 4) in the third direction DR3.

The third jig JG3 may be disposed in the opening OP defined by the second jig JG2. The third jig JG3 may be connected to (e.g., directly connected thereto) the bar CNP and be disposed under the bar CNP (e.g., in a direction opposite to the third direction DR3). The third jig JG3 and the bar CNP may be disposed in the opening OP. In an embodiment, at least a portion of the third jig JG3 and the bar CNP may pass through (e.g., extend through) the second jig JG2 in the second direction DR2. In an embodiment, the third jig JG3 may include a heating wire. Since the third jig JG3 includes a heating wire, the heat bonding molding of the display panel DP may be performed during the bonding process of the display panel DP.

In an embodiment, a lower surface of the second jig JG2 may be disposed to be lower than a lower surface of the third jig JG3 (e.g., in a direction opposite to the third direction DR3). For example, the lower surface of the third jig JG3 may be disposed after being moved in the third direction DR3 higher than the lower surface of the second jig JG2. Alternatively, in an embodiment the lower surface of the second jig JG2 may be disposed to be higher than the lower surface of the third jig JG3 (e.g., in the third direction DR3). For example, the lower surface of the second jig JG2 may be disposed after being moved in the third direction DR3 higher than the lower surface of the third jig JG3. The lower surface of the second jig JG2 may be disposed to be higher than the lower surface of the third jig JG3, and thus, in the molding process of the display panel DP, which will be described later, the display panel DP may first directly contact the third jig JG3, and then directly contact the second jig JG2 to proceed with the process. For example, the first jig JG1 may directly contact the second jig JG2 after first directly contacting the third jig JG3, and the third jig JG3 is moved in the third direction DR3 along the opening defined by the second jig JG2 when the first jig JG1 is moved upward (e.g., in the third direction DR3).

FIG. 11 is a perspective view of an electronic device including a display panel manufactured by using a panel forming apparatus according to an embodiment of the present disclosure.

Referring to FIG. 11, an electronic device ED according to an embodiment of the present disclosure may have long sides that extend in parallel in the first direction DR1 and short sides that extend in parallel in the second direction DR2. Corners of the electronic device ED, which connect the long sides and the short sides of the electronic device ED to each other may have a curved shape. The corners of the electronic device ED having the curved shape may be referred to as rounded corners. A shape of the electronic device ED may be defined as a round-cornered rectangular shape.

Images IM generated by the electronic device ED may be provided to the user through the upper surface of the electronic device ED, viewed in the third direction DR3. The upper surface of the electronic device ED may include a display area D-DA and a peripheral area D-NDA around the display area D-DA (e.g., in a plan view). The display area D-DA may display an image, and the peripheral area D-NDA may not display an image. The peripheral area D-NDA may surround the display area D-DA (e.g., completely or partially surround in a plan view) and may define a periphery of the electronic device ED printed in a predetermined color.

In an embodiment, the upper surface of the electronic device ED may include a flat surface part PPT that is flat, and an edge part EG having a curved surface. The flat surface part PPT may extend in a plane that is defined by the first and second directions DR1 and DR2. The edge part EG may surround the flat surface part PPT (e.g., in a plan view). The edge part EG may extend from the flat surface part PPT to form a curved surface towards an outer lower side. The edge part EG may have a specific curvature. In an embodiment, the display area D-DA may be defined in a flat surface part PPT, and a portion of the edge part EG, which is adjacent to the flat surface part PPT.

Although it is illustrated that the electronic device ED is a mobile phone, by way of example, the electronic device ED is not necessarily limited thereto, and the electronic device ED may be used in various electronic devices. For example, an electronic device ED may be used in large electronic devices, such as televisions, monitors, or external billboards. Furthermore, the electronic device ED may also be used in small and medium-sized electronic devices, such as personal computers, laptop computers, car navigation devices, game consoles, tablets, or cameras. The electronic device ED may be various other small-sized, medium-sized or large-sized electronic devices.

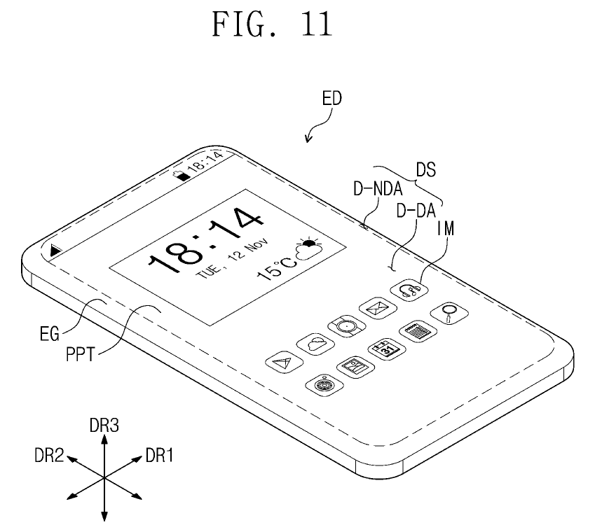

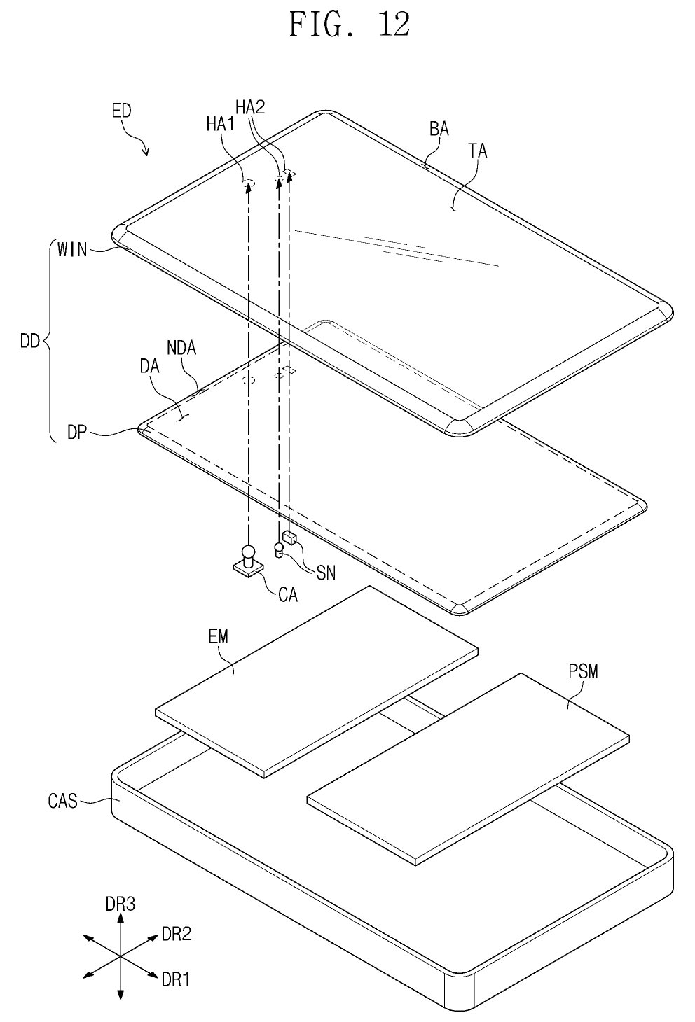

FIG. 12 is an exploded perspective view of an electronic device according to an embodiment.

Referring to FIG. 12, in an embodiment the electronic device ED may include a window WIN, a display panel DP, and a case CAS, and a display device DD may include the window WIN and the display panel DP. The window WIN and the case CAS may be coupled to each other to define an exterior of the electronic device ED, and provide an internal space, in which components of the electronic device ED, such as the display panel DP, may be accommodated.

The window WIN may be disposed on the display panel DP (e.g., in the third direction DR3). The window WIN may protect the display panel DP from an external impact. A front surface of the window WIN may correspond to a display surface IS of the electronic device ED described above. The front surface of the window WIN may include a transmission area TA and a bezel area BA.

The transmission area TA of the window WIN may be an optically transparent area. The window WIN may transmit an image provided by the display panel DP through the transmission area TA, and the user may visually recognize the image. The transmission area TA may correspond to (e.g., overlap with in the third direction DR3) a display area DA of the electronic device ED.

The window WIN may include an optically transparent insulating material. For example, in an embodiment the window WIN may include glass, sapphire, or plastic. The window WIN may have a single-layered or multi-layered structure. In an embodiment, the window WIN may further include functional layers, such as an anti-fingerprint layer, a phase control layer, and a hard coating layer, which are disposed on an optically transparent substrate.

The bezel area BA of the window WIN may be provided as an area, in which a material including a specific color is deposited, coated, or printed. The bezel area BA of the window WIN may prevent a component of the display panel DP, which is disposed to overlap the bezel area BA, from being visually recognized outside (e.g., to a user). The bezel area BA may correspond to (e.g., overlap with in the third direction DR3) the peripheral area D-NDA of the electronic device ED.

At least one first hole area HA1 and a plurality of second hole areas HA2 may be defined in the window WIN. A camera CA may be disposed in the first hole area HA1, and sensors SN may be disposed in the second hole areas HA2.

The display panel DP may display an image in response to an electrical signal. The display panel DP may include a display area DA, and a peripheral area D-NDA that is adjacent to the display area DA (e.g., in a plan view).

The display area DA may be a portion corresponding to the display area D-DA (FIG. 11) of the electronic device ED. The display area DA may be activated depending on an electrical signal. The display area DA may be an area that outputs an image provided from the display panel DP. The display area DA of the display panel DP may correspond to the above-described transmission area TA. In the specification, “an area/portion corresponds to another area/portion” means “an area/portion overlaps another area/portion” (e.g., in a plan view), and is not limited to having the same area and/or the same shape. The image displayed on the display area DA may be visually recognized from the outside through the transmission area TA.

A non-display area NDA may be adjacent to the display area DA. For example, the non-display area NDA may surround the display area DA (e.g., partially or completely surround the display area DA in a plan view). However, embodiments of the present disclosure are not necessarily limited thereto, and the non-display area NDA may be defined in various shapes. The non-display area NDA may be a portion corresponding to a peripheral area D-NDA (FIG. 11) of the electronic device ED. The non-display area NDA may be an area, in which driving circuits or driving wirings for driving the display area DA, various signal lines that provide electrical signals, and pads are disposed. The non-display area NDA of the display panel DP may correspond to the above-described bezel area BA. Components of the display panel DP disposed in the non-display area NDA may be prevented from being visually recognized by the bezel area BA.

The display panel DP according to an embodiment may be a light emitting display panel, and the present disclosure is not particularly limited thereto. For example, in some embodiments the display panel DP may be an organic light emitting display panel, an inorganic light emitting display panel, or a quantum dot light emitting display panel. A light emission layer of the organic light emitting display panel may include an organic light emitting material, and a light emission layer of the inorganic light emitting display panel may include an inorganic light emitting material. A light emission layer of the quantum dot light emitting display panel may include a quantum dot and a quantum rod. Hereinafter, it will be described that the display panel DP is an organic light emitting display panel.

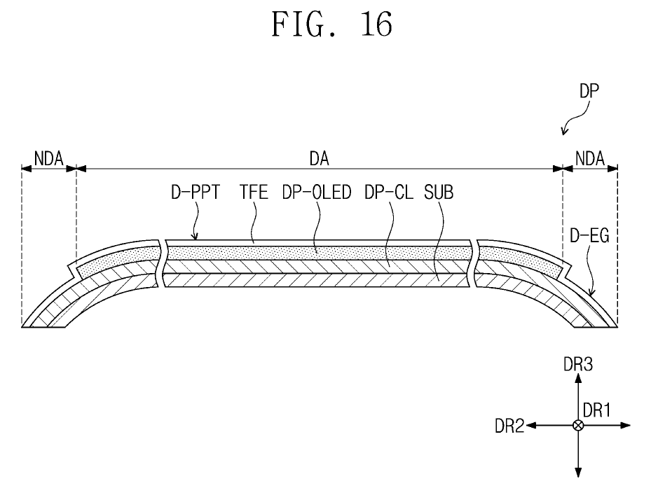

In an embodiment, as shown in FIG. 16 the display panel DP may include a substrate SUB, a circuit element layer DP-CL, a display element layer DP-OLED, and a thin film encapsulation layer TFE. The layers of the display panel DP will be described later in more detail.

The case CAS may be disposed under the display panel DP to accommodate the display panel DP. The case CAS may absorb an impact applied from the outside, and may protect the display panel DP by preventing foreign substance/moisture that penetrates into the display panel DP. The case CAS according to an embodiment may be provided in a form, in which a plurality of accommodation members are coupled to each other.

In an embodiment, the display panel DP may further include an input sensing unit. The input sensing unit may acquire coordinate information of an external input applied from the outside of the electronic device ED. For example, the input sensing unit may be disposed directly on the display panel DP through a continuous process. However, embodiments of the present disclosure are not necessarily limited thereto. In an embodiment, the input sensing unit may be separately manufactured and attached to the display panel DP through an adhesive layer.

FIG. 13 is a block diagram of the electronic device illustrated in FIG. 12.

Referring to FIG. 13, the electronic device ED may include an electronic module EM, a power module PSM, a display device DD, and an electronic optical module ELM. The electronic module EM may include a control module 10, a wireless communication module 20, an image input module 30, a sound input module 40, a sound output module 50, a memory 60, and an external interface module 70. The modules may be mounted on a circuit board or may be electrically connected through a flexible circuit board. The electronic module EM may be electrically connected to the power supply module PSM.

The control module 10 may control an overall operation of the electronic device ED. For example, the control module 10 may activate or deactivate the display device DD according to a user input. The control module 10 may control the image input module 30, the sound input module 40, and the sound output module 50 according to a user input. The control module 10 may include at least one microprocessor.

The wireless communication module 20 may transmit/receive a wireless signal with another terminal by using Bluetooth or Wi-Fi. The wireless communication module 20 may transmit/receive voice signals by using general communication lines. The wireless communication module 20 may include a transmission circuit 22 that modulates and transmits a transmission signal, and a reception circuit 24 that demodulates the received signal.

The image input module 30 may convert an image signal into image data to be displayed on the display device DD by processing the image signal. The sound input module 40 may receive an external sound signal from a microphone in a recording mode and a speech recognition mode, or the like and then may convert the external sound signal into electrical voice data. The sound output module 50 may convert audio data received from the wireless communication module 20 or audio data stored in the memory 60 and then may output the converted data to the outside.

The external interface module 70 may operate as an interface that connects to an external charger, a wired/wireless data port, a card socket (e.g., a memory card, a SIM/UIM card, or the like), or the like.

The power module PSM may supply power necessary for overall operations of the electronic device ED. The power module PSM may include a general battery device.

The electronic optical module ELM may be an electronic component that outputs or receives an optical signal. The electronic optical module ELM may transmit or receive an optical signal through a partial area of the display device DD. In an embodiment, the electronic optical module ELM may include a camera module CAM and a sensor module SNM. The camera module CAM may include the camera CA illustrated in FIG. 12. The sensor module SNM may include the sensor SN illustrated in FIG. 12.

The electronic device ED may include a camera module CAM, and may include the display device DD that displays an image corresponding to the captured image acquired through the camera module CAM. The display device DD may include a case CAS (see FIG. 12) that accommodates the camera module CAM.

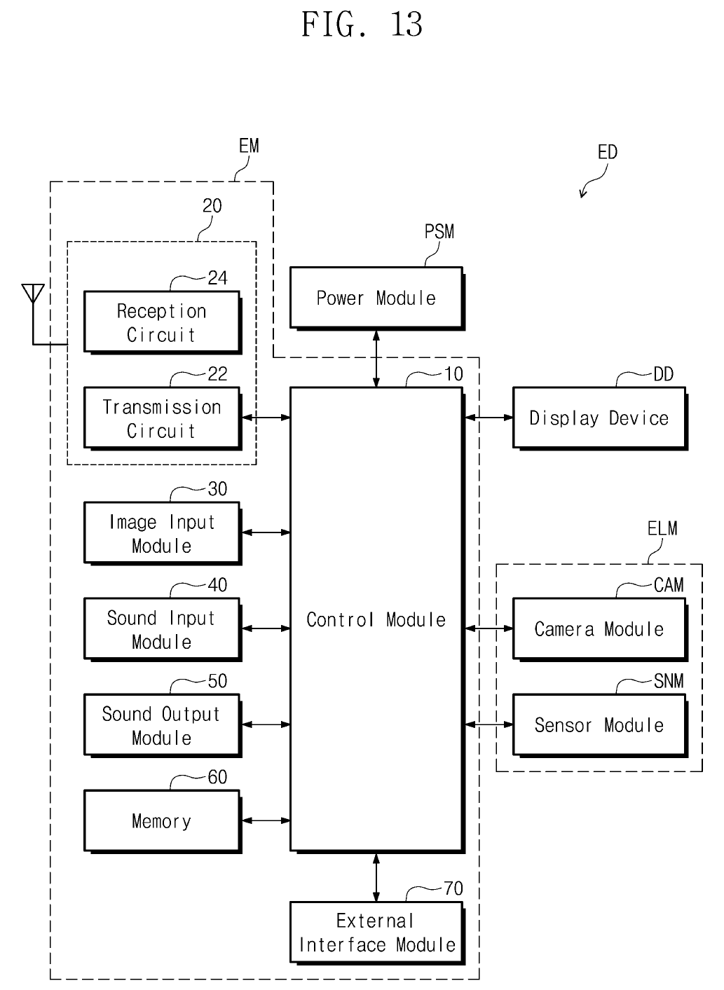

FIG. 14 is a cross-sectional view of a display module and a window of a display device illustrated in FIG. 12.

By way of example, FIG. 14 illustrates cross-sections of the display panel DM and the window WIN, when viewed in the first direction DR1.

Referring to FIG. 14, the display device DD may include a display module DM and a window WIM that is disposed on the display module DM (e.g., in the third direction DR3). The window WIN may protect the display module DM from external scratches and impacts.

The display module DM may include a flat surface part D-PPT, and an edge part D-EG that extends from the flat surface part D-PPT and has a curved surface. The window WIN may include a flat surface part W-PPT, and an edge part W-EG that extends from the flat surface part W-PPT and has a curved surface.

When viewed on a plane, the flat surface part D-PPT of the display module DM and the flat surface part W-PPT of the window WIN may overlap each other. When viewed on a plane, the edge part D-EG of the display module DM and the edge part W-EG of the window WIN may overlap each other.

The flat surface part D-PPT of the display module DM and the flat surface part W-PPT of the window WIN may correspond to the flat surface part PPT (see FIG. 11) of the display device DD. The edge part D-EG of the display module DM and the edge part W-EG of the window WIN may correspond to the edge part EG (see FIG. 11) of the display device DD.

In an embodiment, the display module DM and the window WIN may have shapes corresponding to the display device DD illustrated in FIG. 11. For example, the display module DM and the window WIN may have a round-cornered quadrangular shape corresponding to the display device DD.

In an embodiment, an adhesive layer AL may be disposed between the display module DM and the window WIN (e.g., in the third direction DR3). The display module DM and the window WIN may be bonded to each other by the adhesive layer AL. In an embodiment, the adhesive layer AL may include a pressure sensitive adhesive PSA or an optically clear adhesive OCA, but the type of adhesive is not necessarily limited thereto.

The display area DA may be defined in a flat surface part PPT, and a portion of the edge part EG, which is adjacent to the flat surface part PPT. Accordingly, a portion of the edge part EG, which is adjacent to the flat surface part PPT, may display an image.

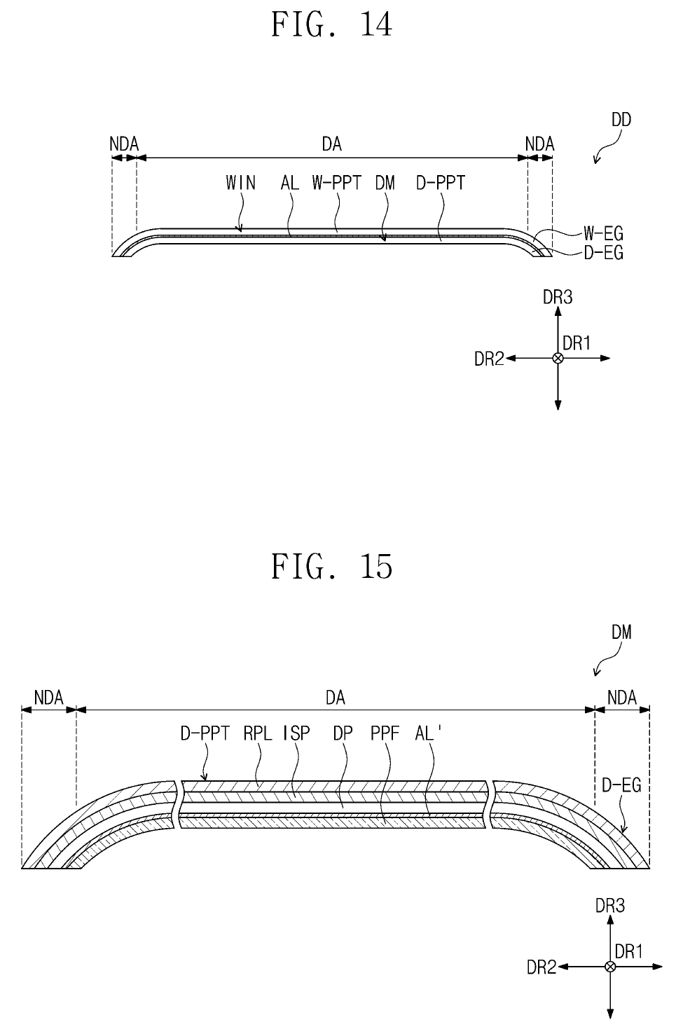

FIG. 15 is a view illustrating a cross section of the display panel illustrated in FIG. 14, by way of example.

By way of example, FIG. 11 illustrates a cross-section of the display module DM, when viewed in the first direction DR1.

Referring to FIG. 15, in an embodiment the display module DM may include a display panel DP, an input sensing part ISP, a reflection prevention layer RPL, a panel protection film PPF, and an adhesive layer AL’.

The input sensing part ISP may be disposed on the display panel DP (e.g., disposed directly thereon in the third direction DR3). In an embodiment, the input sensing part ISP may include a plurality of sensing parts for sensing an external input in a capacitive scheme. When the display device DD is manufactured, the input sensing part ISP may be directly manufactured on the display panel DP. However, embodiments of the present disclosure are not necessarily limited thereto, and the input sensing part ISP may be manufactured as a separate panel from the display panel DP and attached to the display panel DP by an adhesive layer.

The reflection prevention layer RPL may be disposed on the input sensing part ISP (e.g., in the third direction DR3). In an embodiment, when the display device DD is manufactured, the reflection prevention layer RPL may be directly manufactured on the input sensing part ISP. However, embodiments of the present disclosure are not necessarily limited thereto, and the reflection prevention layer RPL may be manufactured as a separate panel, and may be attached to the input sensing part ISP by an adhesive layer.

The reflection prevention layer RPL may be defined as an external light anti-reflection film. The reflection prevention layer RPL may reduce the reflectance of external light incident from the top surface of the display device DD towards the display panel DP. The external light may not be perceived to a user by the reflection prevention layer RPL.

When external light directed toward the display panel DP is reflected from the display panel DP and provided again to an external user, the user may visually perceive the external light, like a mirror. In an embodiment, to prevent this phenomenon, the reflection prevention layer RPL may include a plurality of color filters for displaying the same color as the pixels of the display panel DP.

In an embodiment, the color filters may filter the external light to the same color as pixels. In this embodiment, the external light may not be perceived by the user. However, embodiments of the present disclosure are not necessarily limited thereto, and the reflection prevention layer RPL may include a phase retarder and/or a polarizer to reduce the reflectance of external light.

The panel protection film PPF may be disposed under the display panel DP (e.g., in a direction opposite to the third direction DR3). The panel protection film PPF may protect a bottom surface of the display panel DP. In an embodiment, the panel protection film PPF may include a flexible plastic material such as Polyethyleneterephthalate (PET).

In an embodiment, the adhesive layer AL’ may be interposed between the display panel DP and the panel protection film PPF (e.g., in the third direction DR3). The display panel DP and the panel protection film PPF may be tightly coupled to each other by the adhesive layer AL’. In an embodiment, the adhesive layer AL’ may include a pressure sensitive adhesive or an optically clear adhesive, but the type of adhesive is not necessarily limited thereto.

FIG. 16 is a view illustrating a cross section of the display panel illustrated in FIG. 15, by way of example.

By way of example, FIG. 16 illustrates a cross-section of the display panel DD, when viewed in the first direction DR1.

Referring to FIG. 16, in an embodiment the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

In an embodiment, the display panel DP may include a flat surface part D-PPT, and an edge part D-EG that extends from the flat surface part D-PPT and has a curved surface. By way of example, the flat surface part D-PPT and the edge part D-EG of the display panel DP are illustrated with the same signs as those of the flat surface part D-PPT and the edge part D-EG of the display module DM.

The substrate SUB may include the display area DA and the non-display area NDA around the display area DA (e.g., in a plan view). In an embodiment, the substrate SUB may include glass or may include a flexible plastic material, such as or polyimide (PI).

The display element layer DP-OLED may be disposed in the display area DA. The display element layer DP-OLED may generate an image. The display element layer DP-OLED may be disposed at a portion of the edge part D-EG, which is adjacent to the flat surface part D-PPT and the flat surface part D-PPT. Accordingly, an image may be displayed at a portion of the edge part D-EG, which is adjacent to the flat surface part D-PPT.

A plurality of pixels may be disposed on the circuit element layer DP-CL and the display element layer DP-OLED. Each of the pixels may include a transistor that is disposed on the circuit element layer DP-CL and a light emitting element that is disposed on the display element layer DP-OLED and is connected to the transistor.

The thin film encapsulation layer TFE may be disposed on the circuit element layer DP-CL (e.g., in the third direction DR3) so as to cover the display element layer DP-OLED. The thin film encapsulation layer TFE may protect pixels from moisture, oxygen, and foreign objects.

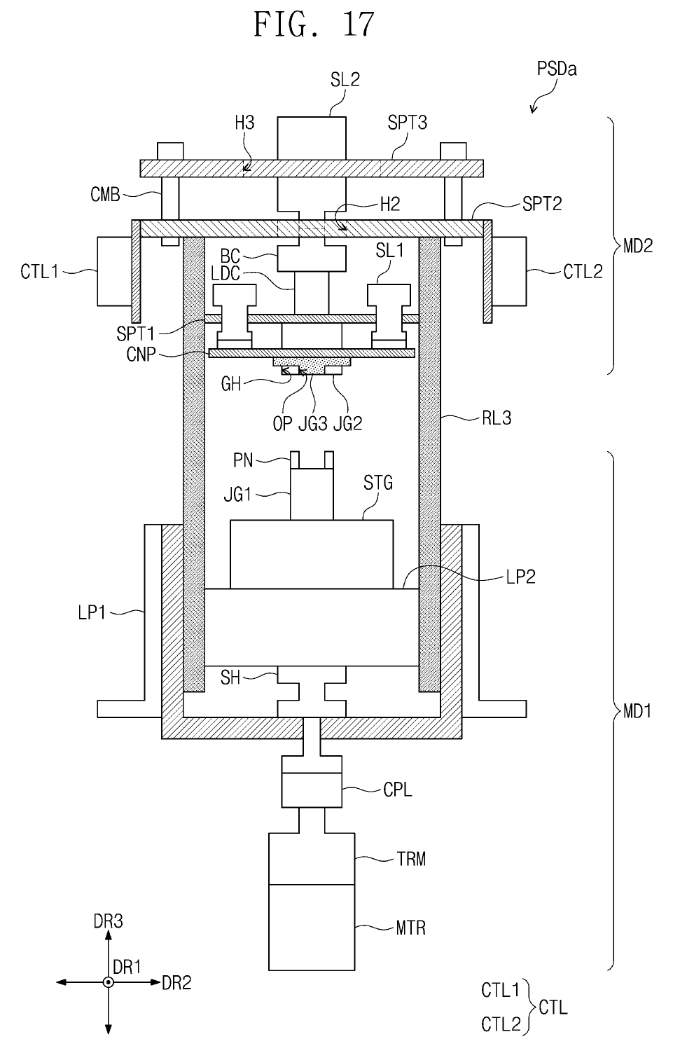

FIG. 17 is a side view of a panel forming apparatus according to an embodiment of the present disclosure.

Referring to FIG. 17, the panel forming apparatus PSDa may further include a third rail RL3 that is connected to (e.g., directly connected thereto) the first mold MD1 and the second mold MD2. In an embodiment, the third rail RL3 may be connected to (e.g., directly connected thereto) a side surface of the first support SPT1, a lower surface of the second support SPT2, and the second support part LP2, such as a side surface of the second support part LP2. When the first mold MD1 and the second mold MD2 are moved upwards and downwards, the first mold MD1 and the second mold MD2 may be connected to the third rail RL3 to be moved in the third direction (e.g., the upward/downward direction). The third rail RL3 may reduce or eliminate the misalignment of the display panel DP that may occur due to the upward/downward movements of the first mold MD1 and the second mold MD2 while the first mold MD1 and the second mold MD2 are moved in the upward and downward directions along the third direction DR3.

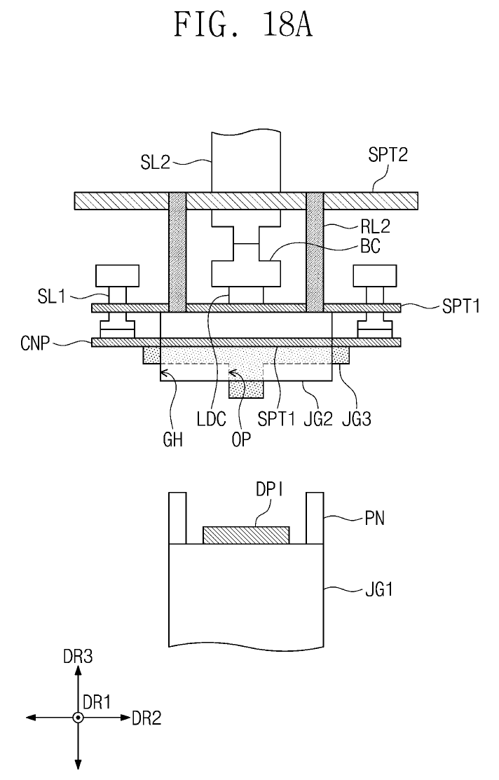

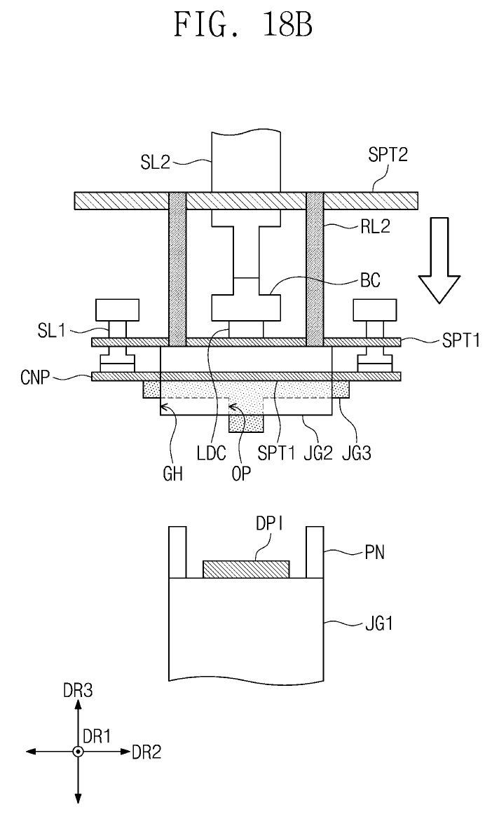

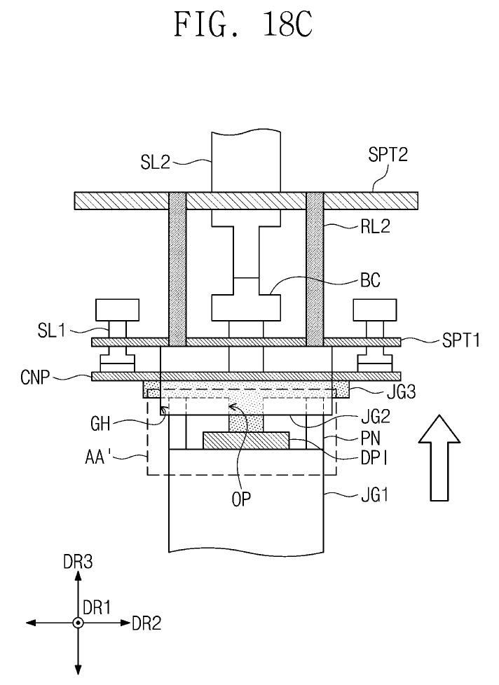

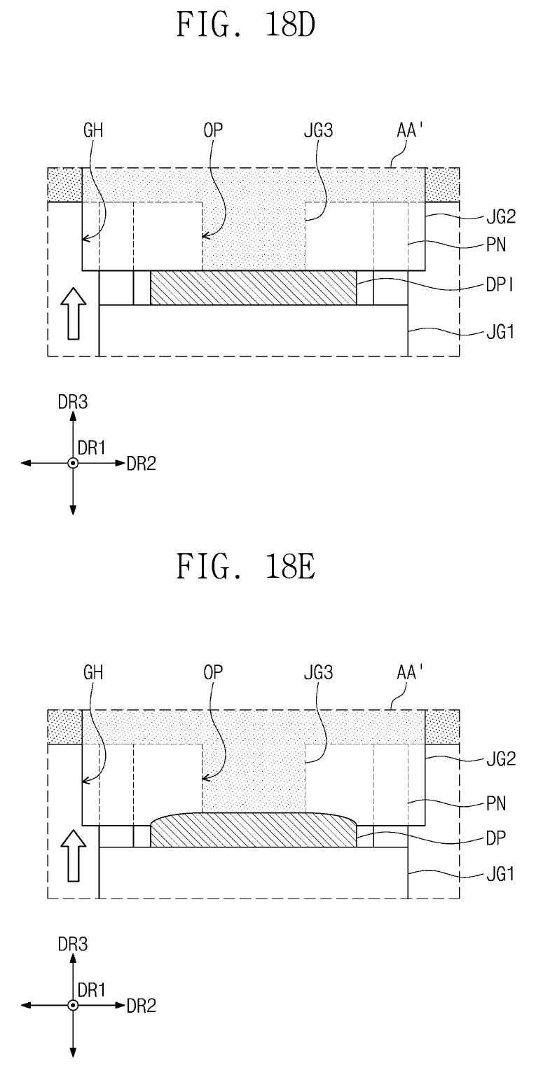

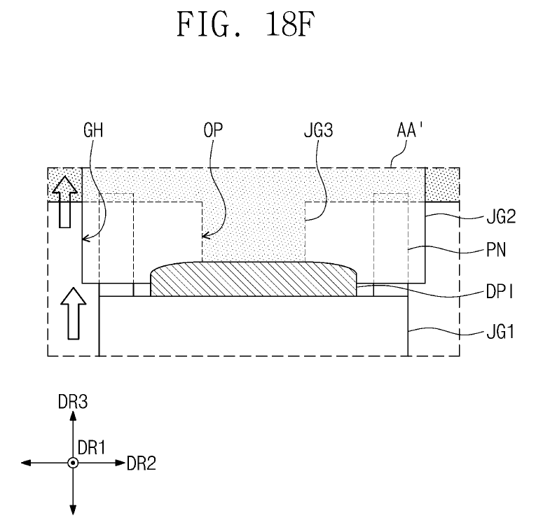

FIGS. 18A to 18F briefly illustrate panel forming apparatus PSD for convenience of description, and the remaining configurations thereof will be omitted. For convenience, the upward direction may be referred to as the third direction DR3, and the downward direction may be referred to as a direction that is opposite to the third direction DR3.

FIGS. 18A to 18C are views illustrating processes of a display panel forming apparatus according to an embodiment of the present disclosure.

Referring to FIG. 18A, the method of forming the display panel DP (e.g., a panel forming method) may include an operation of preparing a first mold MD1 and an operation of preparing a second mold MD2. The method of forming the display panel DP may include an operation of providing a preliminary display panel DPI on a first jig JG1. Fourth holes H4 (see FIG. 4) may be defined in an upper surface of the first jig JG1. In an embodiment, the preliminary display panel DPI may be vacuum-suctioned to the upper surface of the first jig JG1 by the fourth holes H4.

Referring to FIG. 18B, the method of forming the display panel DP may include an operation of applying a thrust to first cylinders SL1 and a second cylinder SL2. When a thrust is applied to the first cylinders SL1 and the second cylinder SL2, the second cylinder SL2 may apply a downward thrust to the first support SPT1. The operation of applying the thrust to the first cylinders SL1 and the second cylinder SL2 may include an operation of applying a first thrust to the first cylinders SL1, respectively, and an operation of applying a second thrust to the second cylinder SL2. The forces of the first thrust and the second thrust may be different from each other. The first cylinders SL1 may be connected to a third jig JG3 via the bar CNP, and the second cylinder SL2 may be connected to a first support SPT1 to be connected to a second jig JG2. A reliability in the process of forming the display panel DP may be increased by differently adjusting the thrusts received by the second jig JG2 and the third jig JG3.

The method of forming the display panel DP may include an operation of moving the first support SPT1 downward due to the thrust of the second cylinder SL2. When the first support SPT1 is moved downward, the second rail RL2 may extend downward. The first support SPT1 may be moved downward so that the second jig JG2 and the third jig JG3 disposed under the first support SPT1 may also be moved downward (e.g., in a direction opposite to the third direction DR3).

Referring to FIG. 18C, the method of forming the display panel DP may include an operation of moving the first jig JG1 in the third direction DR3 (e.g., an upward direction). The first jig JG1 may be moved upward by a force provided by a motor MTR (see FIG. 4).

The method of forming the display panel DP may include an operation of moving the alignment part STG (see FIG. 4) in the first direction DR1 and the second direction DR2 so that the pins PN overlap the guide grooves GH in the third direction DR3. Thereafter, the first jig JG1 may be moved in the third direction DR3 such that the pins PN are coupled to the guide grooves GH in the third direction DR3.

When the first jig JG1 is moved in the third direction DR3, the pins PN may be disposed in guide grooves GH defined in the second jig JG2. For example, the pins PN may be moved in the third direction DR3 along the guide grooves GH that overlap the pins PN in the third direction DR3, respectively. As the pins PN are moved along the guide grooves GH, the first jig JG1 and the second jig JG2 may be connected to each other through the pins PN. When the first jig JG1 and the second jig JG2 are connected to each other and the first jig JG1 is moved upward, the misalignment of the first jig JG1 with the second jig JG2 and the third jig JG3 may be reduced or eliminated.

FIGS. 18D to 18F are enlarged views of portion AA’ of FIG. 18C.

Referring to FIGS. 18C and 18D, the method of forming the display panel DP may include an operation of bringing an upper surface of the preliminary display panel DPI into direct contact with the second jig JG2 or the third jig JG3. In an embodiment, the operation of bringing the upper surface of the preliminary display panel DPI into direct contact with the second jig JG2 or the third jig JG3 may include an operation of bringing the upper surface of the preliminary display panel DPI and the third jig JG3 into direct contact with each other, and an operation of bringing the upper surface of the preliminary display panel DPI and the second jig JG2 and the third jig JG3 into direct contact with each other.

In an embodiment, when the first jig JG1 is moved upward (e.g., in the third direction DR3), the first jig JG1 may not directly contact the second jig JG2, but may first contact the third jig JG3. Thereafter, the third jig JG3 may be moved in the third direction DR3 along the opening OP. Thereafter, the first jig JG1 may directly contact both the second jig JG2 and the third jig JG3.

In the process, the upper surface of the preliminary display panel DPI disposed on the first jig JG1 may first directly contact the third jig JG3. In an embodiment, when the preliminary display panel DPI first directly contacts the third jig JG3, a center portion of the preliminary display panel DPI in the first direction DR1 and the second direction DR2 may first directly contact the third jig JG3. For example, the flat surface part D-PPT (see FIG. 16) of the display panel DP may first directly contact the third jig JG3. In an embodiment, when the flat surface part D-PPT of the display panel DP first directly contacts the third jig JG3 and the edge part D-EG (see FIG. 16) of the display panel DP first directly contacts the second jig JG2, the preliminary display panel DPI may be bent due to the thrust received by the second jig JG2 to eliminate or reduce the misalignment of the preliminary display panel DPI.

In an embodiment, the operation of bringing the upper surface of the preliminary display panel DPI into direct contact with the second jig JG2 or the third jig JG3 may include an operation of bringing the upper surface of the preliminary display panel DPI and the second jig JG2 into direct contact with each other, and an operation of bringing the upper surface of the preliminary display panel DPI and both the second jig JG2 and the third jig JG3 into direct contact with each other.

In an embodiment, a lower surface of the third jig JG3 may be disposed in more of an upward direction (e.g., in the third direction DR3) than a lower surface of the second jig JG2. When the first jig JG1 is moved upward, the first jig JG1 may not directly contact the third jig JG3, but may first directly contact the second jig JG2. Thereafter, the first jig JG1 may directly contact the second jig JG2 and the third jig JG3. When a phenomenon, in which the preliminary display panel DPI is bent due to the thrust received by the second jig JG2 and the misalignment of the preliminary display panel DPI may be reduced, the second jig JG2 may first directly contact the preliminary display panel DPI.

Referring to FIGS. 18E and 18F, the first jig JG1 may be moved upward to form the display panel DP. The edge part D-EG of the display panel DP may have a round shape. While the first jig JG1 continues to be moved upward, the second jig JG2 and the third jig JG3 may be moved upward (e.g., in the third direction DR3). While the first jig JG1 is moved upward and the first jig JG1 moves the second jig JG2 and the third jig JG3 in the upward direction simultaneously with the first jig JG1, the second jig JG2 and the third jig JG3 may apply a specific thrust to the display panel DP.

In an embodiment, the method of forming the display panel DP may include an operation of stopping the first mold MD1. For example, the first jig JG1 may not be moved upward (e.g., in the third direction DR3) and is stopped, so that the first jig JG1, the second jig JG2, and the third jig JG3 may be stopped. Molding of the display panel DP may be completed.

According to the above description, the first jig and the second jig may be connected through the pins while the pins are moved along the guide grooves, respectively. When the first jig is moved upward, the misalignment of the first jig with the second jig and the third jig may be reduced or eliminated.

The first cylinders may apply a constant thrust to the third jig. The second cylinder may apply a constant thrust to the second jig. The second jig and the third jig may apply a specific thrust to the display panel while the first jig moves the second jig and the third jig in the upward direction at the same time.

After the flat surface part of the display panel first directly contacts the third jig, the edge part of the display panel may then directly contact the second jig. A phenomenon, in which the edge part of the display panel is bent due to the thrust received by the second jig and the display panel is misaligned, may be eliminated or reduced.

Although non-limiting embodiments of the present disclosure have been described for illustrative purposes, those skilled in the art will appreciate that various modifications, and substitutions are possible, without departing from the scope and spirit of the present disclosure. Accordingly, the technical scope of the present disclosure should not be limited to embodiments described in the detailed description of the specification.

What is claimed is:

1. A panel forming apparatus comprising:
a first mold; and
a second mold disposed on the first mold,
wherein the first mold includes:
an alignment part;
a first jig disposed on the alignment part; and
a shaft disposed under the alignment part, the shaft moves the alignment part and the first jig upward and downward, and
wherein the second mold includes:
a first support including a plurality of first holes defined therein;
a second jig disposed under the first support, the second jig including an opening defined therein;
a third jig disposed in the opening;
a plurality of first cylinders disposed on the first support, the plurality of first cylinders extending through the plurality of first holes, respectively, and connected to the third jig; and
a second cylinder disposed on the first support.

2. The panel forming apparatus of claim 1, wherein:
the first mold includes a plurality of pins disposed on the first jig, the plurality of pins is arranged to be spaced apart from each other in a first direction and a second direction crossing the first direction,
wherein the plurality of pins extends in a third direction perpendicular to the first direction and the second direction, the first jig moves upward and downward along the third direction , and
wherein the plurality of pins overlap a plurality of guide grooves defined at a periphery of the second jig, the plurality of guide grooves extending in the third direction.

3. The panel forming apparatus of claim 2, wherein the plurality of pins is disposed in the plurality of guide grooves and moves in the third direction along the plurality of guide grooves when the first jig is moved in the third direction.

4. The panel forming apparatus of claim 1, wherein a lower surface of the second jig is disposed to be higher than a lower surface of the third jig.

5. The panel forming apparatus of claim 1, wherein the first jig contacts the second jig after first contacting the third jig, and the third jig is moved in the third direction along the opening when the first jig is moved upward due to the first jig contacting the third jig.

6. The panel forming apparatus of claim 1, wherein the first jig contacts the third jig after contacting the second jig first when the first jig is moved upward.

7. The panel forming apparatus of claim 1, wherein the first jig, the second jig, and the third jig include a heating wire.

8. The panel forming apparatus of claim 1, wherein:
the second mold further includes a second support disposed on the first support, the second support includes a second hole defined therein; and
the second cylinder extends through the second hole.

9. The panel forming apparatus of claim 8, wherein the second mold further includes:
a third support disposed on the second support; and
a plurality of coupling parts coupling the second support and the third support to each other.

10. The panel forming apparatus of claim 8, wherein:
the first mold further includes a first rail disposed on a side surface of the alignment part; and
the second mold further includes a second rail connected to the first support and the second support.

11. The panel forming apparatus of claim 1, wherein a plurality of fourth holes is defined on an upper surface of the first jig.

12. The panel forming apparatus of claim 1, wherein the second mold further includes a bar disposed on lower surfaces of the plurality of first cylinders and an upper surface of the third jig.

13. The panel forming apparatus of claim 1, wherein the second mold further includes:
a measurement part disposed on the first support, and positioned at centers of the plurality of first cylinders in a first direction; and
a bracket disposed on an upper surface of the measurement part, and disposed on a lower surface of the second cylinder.

14. The panel forming apparatus of claim 1, further comprising:
a third rail connected to the first mold and the second mold.

15. A panel forming method comprising:
preparing a first mold including an alignment part, a first jig disposed on the alignment part, and a shaft disposed under the alignment part, the shaft moves the alignment part and the first jig upward and downward;
preparing a second mold including a first support including a plurality of first holes defined therein, a second jig disposed under the first support, the second jig including an opening defined therein, a third jig disposed in the opening, a plurality of first cylinders disposed on the first support, the plurality of first cylinders extending through the plurality of first holes, respectively, and connected to the third jig, and a second cylinder disposed on the first support;
providing a preliminary display panel onto the first jig;
applying a thrust to the plurality of first cylinders and the second cylinder;
moving the first support downward;
moving the first jig upward;
bringing an upper surface of the preliminary display panel and the second jig or the third jig into contact with each other; and
stopping the first mold.

16. The panel forming method of claim 15, wherein the first mold includes a plurality of pins disposed on the first jig, the plurality of pins is arranged to be spaced apart from each other in a first direction and a second direction crossing the first direction,
wherein a plurality of guide grooves extending in a third direction perpendicular to the first direction and the second direction are defined at a periphery of the second jig, and
wherein the panel forming method further includes:
moving the alignment part in the first direction and the second direction so that the plurality of pins overlap the plurality of guide grooves in the third direction; and
moving the plurality of pins in the third direction and coupling the plurality of pins to the plurality of guide grooves.

17. The panel forming method of claim 15, wherein the bringing of the upper surface of the preliminary display panel and the second jig or the third jig into contact with each other includes:
bringing the upper surface of the preliminary display panel and the third jig into contact with each other; and
after bringing the upper surface of the preliminary display panel and the third jig into contact with each other, bringing the upper surface of the preliminary display panel and the second jig and the third jig into contact with each other.

18. The panel forming method of claim 15, wherein the bringing of the upper surface of the preliminary display panel and the second jig or the third jig into contact with each other includes:
bringing the upper surface of the preliminary display panel and the second jig into contact with each other; and
after bringing the upper surface of the preliminary display panel and the second jig into contact with each other, bringing the upper surface of the preliminary display panel and both the second jig and the third jig into contact with each other.

19. The panel forming method of claim 15, wherein the applying of the thrust to the first cylinders and the second cylinder includes:
applying a first thrust to the plurality of first cylinders, respectively; and
applying a second thrust to the second cylinder, and
wherein the first thrust and the second thrust are different from each other.

20. An electronic device comprising:
a camera module;
a display device displaying an image corresponding to a captured image acquired through the camera module; and
a case accommodating the display device and the camera module,
wherein the display device includes a display panel formed by a first mold and a second mold facing each other upward and downward and being moved to become closer to each other upward and downward, and including an edge part having a round shape,
wherein the first mold includes:
an alignment part;
a first jig disposed on the alignment part; and
a shaft disposed under the alignment part, the shaft moves the alignment part and the first jig upward and downward, and
wherein the second mold includes:
a first support including a plurality of first holes defined therein;
a second jig disposed under the first support, the second jig including an opening defined therein;
a third jig disposed in the opening;
a plurality of first cylinders disposed on the first support, the plurality of first cylinders extending through the plurality of first holes, respectively, and connected to the third jig; and
a second cylinder disposed on the first support.
